(19) United States
(12) Patent Application Publication
(10) Pub. No.: US 2001/0046766 A1
(43) Pub. Date: Nov. 29, 2001

(54) Semiconductor devices and methods for manufacturing the same

(76) Inventor: Tsutomu Asakawa, Shiojiri-shi (JP)

Correspondence Address: KONRAD RAYNES VICTOR & MANN, LLP, 315 SOUTH BEVERLY DRIVE, SUITE 210, BEVERLY HILLS, CA, 90212, US

(21) Appl. No.: 09/818,142

(22) Filed: Mar. 27, 2001

(30) Foreign Application Priority Data
Mar. 28, 2000 (JP) 2000-88819(P)

(51) Int. Cl. H01L 21/4763; H01L 29/40

(52) U.S. Cl. 438/648; 257/769

(57) ABSTRACT

Certain embodiments of the present invention relate to a method for manufacturing a MOS field effect transistor in which a silicon-containing layer can be readily formed over source/drain regions. A polycrystal silicon layer (amorphous silicon layer) 17 is formed over the entire surface of a p type silicon substrate 11 by a CVD method. Then, the polycrystal silicon layer (amorphous silicon layer) 17, the polycrystal silicon layer 19, the sidewall dielectric layers 25a and 25b, and the field oxide layers 27a and 27b are polished by a CMP method. As a result, the polycrystal silicon layer (amorphous silicon layer) 17a is isolated from the polycrystal silicon layer 19 by the sidewall dielectric layer 25a. Also, the polycrystal silicon layer (amorphous silicon layer) 17b is isolated from the polycrystal silicon layer 19 by the sidewall dielectric layer 25b.

Japanese Patent Application No. 2000-088819, filed Mar. 28, 2000, is hereby incorporated by reference in its entirety.

### TECHNICAL FIELD

The present invention relates to semiconductor devices having a silicide layer and methods for manufacturing the same.

### RELATED ART

Due to the miniaturization of MOS (Metal Oxide Semiconductor) field effect transistors, their gate lengths become shorter. Shortened gate lengths result in punch-through. Punch-through is a phenomenon in which a depletion layer extending from a source region connects to a depletion layer extending from a drain region. When this phenomenon occurs, current always flows between the source region and the drain region, and therefore current cannot be controlled by the gate electrode. A source (drain) region may be made shallow as a counter measure to prevent the punch-through.

On the other hand, in a MOS field effect transistor, a silicide layer may be formed over the gate electrode and the source (drain) region. The silicide layer is provided to lower their resistance to improve the speed of the MOS field effect transistor. When the thickness of the silicide layer is made greater, the resistance can be proportionally reduced, and the speed of the MOS field effect transistor can be further improved.

In this manner, in order to prevent the occurrence of punch-through and lower the resistance, the source (drain) region may be made shallower and the silicide layer may be made thicker. However, leak current would increase unless the separation between a bottom of the silicide layer and a bottom of the source (drain) region is greater than a specified distance (for example, 50 nm). In other words, since the source (drain) region is formed within a region (for example, a well) of an opposite conductivity type, a pn junction is formed between the bottom of the source (drain) region and the above-described region. Therefore, unless the separation between the bottom of the silicide layer and the bottom of the source (drain) region is made greater than the above-described distance, leak current at the pn junction increases.

A MOS field effect transistor having an elevated source (drain) structure can solve the problems described above. In other words, by the MOS field effect transistor having an elevated source (drain) structure, the source (drain) region can be made shallow, the silicide layer can be made thicker, and an increase in the leak current at the pn junction can be suppressed.

A MOS field effect transistor having an elevated source (drain) structure is described, for example, in LEDM93, page 839˜page 842, “Novel Elevated Silicide Source/Drain (ESSOD) by Load-Lock LPCVD-SI and Advanced Silicidation Processing”. In the MOS field effect transistor having an elevated source (drain) structure described in this document, a silicon monocrystal layer is formed over the source (drain) region, and a silicide layer is formed over the silicon monocrystal layer. Accordingly, even when the silicide layer is made thicker while the source (drain) region is shallow, the bottom of the source (drain) region and the bottom of the silicide layer can be separated by a distance that does not increase the leak current at the pn junction.

### PROBLEMS WITH THE RELATED ART

In the elevated source/drain structure described in the above document, the silicon monocrystal layer over the source/drain region is formed by an epitaxial growth method. In the epitaxial growth method, a naturally formed oxide film on the surface of the source/drain region needs to be completely removed and water molecules adsorbed thereon need to be removed in order to appropriately grow the silicon monocrystal layer. Accordingly, an LPCVD with Load-Lock and a thorough pre-processing are required.

Furthermore, in the epitaxial growth, wet etching must be conducted in order to remove the polycrystal silicon layer grown on the gate electrode and the element isolation dielectric layer. If the wet etching is not sufficient, problems such as short-circuit between the gate electrode and the source region and short-circuit among MOS field effect transistors may occur.

### SUMMARY

One embodiment relates to a method for manufacturing a semiconductor device, the method comprising forming a conduction layer that becomes a component of a gate electrode and forming a source/drain region. The method also includes forming a silicon-containing layer including at least one of an amorphous silicon layer and a polycrystal silicon layer in a manner to cover the source/drain region and the conduction layer. The silicon-containing layer is partially removed to leave the silicon-containing layer over the source/drain region, and a silicide layer is formed over the silicon-containing layer over the source/drain region.

Another embodiment relates to a method for manufacturing a semiconductor device, the method including forming a first silicon-containing layer that becomes a component of a gate electrode and forming a source/drain region. The method also includes forming a sidewall dielectric layer on a side surface of the first silicon-containing layer, and forming a second silicon-containing layer including at least one of an amorphous silicon layer and a polycrystal silicon layer in a manner to cover the source/drain region and the first silicon-containing layer. The method also includes partially removing the second silicon-containing layer to leave the second silicon-containing layer over the source/drain region. In addition a first silicide layer is formed over the first silicon-containing layer and a second silicide layer is formed over the second silicon-containing layer on the source/drain region.

Another embodiment relates to a method for manufacturing a semiconductor device including forming a first silicon-containing layer that becomes a component of a gate electrode and forming an upper layer over the first silicon-containing layer. A source/drain region is formed. A sidewall dielectric layer is formed on a side surface of a structure including the first silicon-containing layer and the upper layer. The method also includes forming a second silicon-containing layer including at least one of an amorphous silicon layer and a polycrystal silicon layer in a manner to cover the source/drain region and the upper layer. The method also includes partially removing the second silicon-containing layer to leave the second silicon-containing layer over the source/drain region and to expose the upper layer. The upper layer is removed, and a first silicide layer is formed over the first silicon-containing layer and a second silicide layer is formed over the second silicon-containing layer on the source/drain region.

Still another embodiment relates to a semiconductor device having a silicide layer, including a silicon-containing layer and a source/drain region, wherein the silicon-containing layer is positioned over the source/drain region, the silicon-containing layer includes at least one of an amorphous silicon layer and a polycrystal silicon layer, and the silicide layer is positioned over the silicon-containing layer.

Another embodiment relates to a semiconductor device including a source/drain region, a first silicon-containing layer, a second silicon-containing layer, a first silicide layer, a second silicide layer and a sidewall dielectric layer. The first silicon-containing layer and the first silicide layer form a gate electrode. The second silicon-containing layer is positioned over the source/drain region. The second silicon-containing layer includes at least one of an amorphous silicon layer and a polycrystal silicon layer. The second silicide layer is positioned over the second silicon-containing layer. The sidewall dielectric layer is located between the first silicon-containing layer and the second silicon-containing layer. A top portion of the sidewall dielectric layer includes a polished surface.

Another embodiment relates to a semiconductor device including a source/drain region, a first silicon-containing layer, a second silicon-containing layer, a first silicide layer, a second silicide layer and a sidewall dielectric layer. The first silicon-containing layer and the first silicide layer form a gate electrode. The second silicon-containing layer is positioned over the source/drain region. The second silicon-containing layer includes at least one of an amorphous silicon layer and a polycrystal silicon layer. The second silicide layer is positioned over the second silicon-containing layer. The sidewall dielectric layer is located between the first silicon-containing layer and the second silicon-containing layer. In addition, a top portion of the sidewall dielectric layer is pointed.

### BRIEF DESCRIPTION OF THE DRAWINGS

Embodiments of the invention are described with reference to the accompanying drawings which, for illustrative purposes, are schematic and not necessarily drawn to scale.

FIG. 1 is an illustration of a step to describe a method for manufacturing a MOS field effect transistor 1 in accordance with a first embodiment of the present invention.

FIG. 2 is an illustration of a step to describe the method for manufacturing the MOS field effect transistor 1 in accordance with the first embodiment of the present invention.

FIG. 3 is an illustration of a step to describe a method for manufacturing a MOS field effect transistor 3 in accordance with a second embodiment of the present invention.

FIG. 4 is an illustration of a step to describe the method for manufacturing the MOS field effect transistor 3 in accordance with the second embodiment of the present invention.

### DETAILED DESCRIPTION

It is an object of certain embodiments of the present invention to provide semiconductor devices in which a silicon-containing layer can be readily formed over source/drain regions and methods for manufacturing the same.

Certain embodiments of the present invention relate to methods for manufacturing a semiconductor device, including a method comprising the steps of: forming a conduction layer that becomes a component of a gate electrode; forming a source/drain region; forming a silicon-containing layer including at least one of an amorphous silicon layer and a polycrystal silicon layer in a manner to cover the source/drain region and the conduction layer; partially removing the silicon-containing layer to leave the silicon-containing layer over the source/drain region; and forming a silicide layer over the silicon-containing layer over the source/drain region.

The method for manufacturing a semiconductor device described in the above paragraph may use an amorphous silicon layer, a polycrystal silicon layer or the like as a silicon-containing layer. An amorphous silicon layer and a polycrystal silicon layer can be formed by an LPCVD without Load-Lock. Accordingly, an amorphous silicon layer and a polycrystal silicon layer can be readily formed compared to a silicon monocrystal layer that is formed by an epitaxial growth method.

It is noted that, in the above method, the silicide layer may or may not reach the source/drain region. Also, the conduction layer is a layer that is formed from a material having conductivity including, for example, a layer composed of a metal material, a polysilicon layer and an amorphous silicon layer. Also, the source/drain region is a region that functions as at least one of a source region and a drain region. Source/drain regions described below have the same meaning.

In the method for manufacturing a semiconductor device in accordance with certain embodiments of the present invention, the following step may be added. Namely, the step of leaving the silicon-containing layer over the source/drain region includes the step of polishing the silicon-containing layer by a CMP (Chemical Mechanical Polishing) method.

The CMP method described above can completely remove the silicon-containing layer that is formed over the gate electrode and an element isolation dielectric layer. As a result, problems of short-circuit between the gate electrodes and the source region and short-circuit among transistors do not occur. Also, by the CMP method, an upper surface of the gate electrode and an upper surface of the silicon-containing layer that remains over the source/drain region may be formed at the same height. Therefore, photolithography after the CMP step can be readily conducted.

Certain embodiments of the present invention also include a method for manufacturing a semiconductor device comprising the steps of: forming a first silicon-containing layer that becomes a component of a gate electrode; forming a source/drain region; forming a sidewall dielectric layer on a side surface of the first silicon-containing layer; forming a second silicon-containing layer including at least one of an amorphous silicon layer and a polycrystal silicon layer in a manner to cover the source/drain region and the first silicon-containing layer; partially removing the second silicon-containing layer to leave the second silicon-containing layer over the source/drain region; and forming a first silicide layer over the first silicon-containing layer and a second silicide layer over the second silicon-containing layer on the source/drain region.

By the method for manufacturing a semiconductor device having the steps in accordance with the above paragraph, the second silicon-containing layer can be readily formed for the same reasons described above. In addition, the second silicide layer may or may not reach the source/drain region. Also, the first silicon-containing layer is, for example a polysilicon layer or an amorphous silicon layer.

In addition, the following step may be added. Namely, the step of leaving the second silicon-containing layer over the source/drain region includes the step of polishing the first silicon-containing layer, the second silicon-containing layer and the sidewall dielectric layer by a CMP (Chemical Mechanical Polishing) method.

If the polishing amount is too small in the polishing step using the CMP method, a top portion of the sidewall dielectric layer does not reach a width that can avoid contact between the fist silicide layer and the second silicide layer.

On the other hand, if the polishing amount is excessive, the thickness of the second silicon-containing layer becomes small. If the second silicide layer is made thick under this condition, the distance between a bottom of the second silicide layer and a bottom of the source/drain region becomes short, resulting in an increase in the leak current at the pn junction.

Accordingly, the polishing amount by the CMP method is determined in consideration of the factors described above.

Embodiments of the present invention also include a method for manufacturing a semiconductor device, comprising the steps of: forming a first silicon-containing layer that becomes a component of a gate electrode; forming an upper layer over the first silicon-containing layer; forming a source/drain region; forming a sidewall dielectric layer on a side surface of a structure including the first silicon-containing layer and the upper layer; forming a second silicon-containing layer including at least one of an amorphous silicon layer and a polycrystal silicon layer in a manner to cover the source/drain region and the upper layer; partially removing the second silicon-containing layer to leave the second silicon-containing layer over the source/drain region and to expose the upper layer; removing the upper layer; and forming a first silicide layer over the first silicon-containing layer and a second silicide layer over the second silicon-containing layer on the source/drain region.

By the method for manufacturing a semiconductor device having the steps in accordance with the above paragraph, the second silicon-containing layer can be readily formed for the same reasons described above.

In the above method for manufacturing a semiconductor device, the first silicon-containing layer and the second silicon-containing layer are separated from each other by a distance that is equivalent to the thickness of the upper layer. As a result, the first silicon-containing layer and the second silicon-containing layer are provided in such a positional relation that the first silicide layer and the second silicide layer do not contact each other.

The thickness of the upper layer that can be used in the present invention is, for example, 300˜1000 Angstrom. First, the reason for the thickness being 300 Angstrom or greater is described. Since the first silicide layer and the second silicide layer should not contact one another, the first silicon-containing layer and the second silicon-containing layer must be provided in a positional relation in which they can avoid contacting each other. When the thickness of the upper layer is 300 Angstrom or greater, a certainty in attaining such a positional relation can be increased. Next, the reason for the thickness being 1000 Angstrom or less is described. When the thickness of the first silicon-containing layer becomes too small, the first silicide layer may contact the gate dielectric layer, and the dielectric characteristic of the gate dielectric layer is adversely affected. The upper layer having a thickness of 1000 Angstrom or less can prevent the thickness of the first silicon-containing layer from becoming excessively small.

For example, titanium nitride can be used as the upper layer that can be used in the present invention. The upper layer may be removed by a method using, for example, a mixed solution of ammonia water and hydrogen peroxide water.

It is noted that, in the above method for manufacturing a semiconductor device, the second silicide layer may or may not reach the source/drain region. Also, the first silicon-containing layer is, for example a polysilicon layer or an amorphous silicon layer.

In the above method for manufacturing a semiconductor device in accordance with the present invention, the following step may be added. Namely, the step of leaving the second silicon-containing layer over the source/drain region and exposing the upper layer includes the step of polishing the second silicon-containing layer by a CMP (Chemical Mechanical Polishing) method.

Embodiments of the present invention also provide a semiconductor device having a silicide layer, the semiconductor device comprising: a silicon-containing layer and a source/drain region, wherein the silicon-containing layer is positioned over the source/drain region, the silicon-containing layer includes at least one of an amorphous silicon layer and a polycrystal silicon layer, and the silicide layer is positioned over the silicon-containing layer.

The semiconductor device embodiment having the structure in accordance with the above paragraph may use an amorphous silicon layer, a polycrystal silicon layer or the like as a silicon-containing layer. Accordingly, a method that is easier than an epitaxial growth method can be used to form the silicon-containing layer.

Certain embodiments of the present invention also include a semiconductor device that comprises a source/drain region, a first silicon-containing layer, a second silicon-containing layer, a first silicide layer, a second silicide layer and a sidewall dielectric layer, wherein the first silicon-containing layer and the first silicide layer form a gate electrode, the second silicon-containing layer is positioned over the source/drain region, the second silicon-containing layer includes at least one of an amorphous silicon layer and a polycrystal silicon layer, the second silicide layer is positioned over the second silicon-containing layer, the sidewall dielectric layer is located between the first silicon-containing layer and the second silicon-containing layer, and a top portion of the sidewall dielectric layer includes a polished surface.

The semiconductor device having the above structure may achieve the same effects as those of the semiconductor device described earlier.

Certain embodiments of the present invention also provide a semiconductor device comprising: a source/drain region, a first silicon-containing layer, a second silicon-containing layer, a first silicide layer, a second silicide layer and a sidewall dielectric layer, wherein the first silicon-containing layer and the first silicide layer form a gate electrode, the second silicon-containing layer is positioned over the source/drain region, the second silicon-containing layer includes at least one of an amorphous silicon layer and a polycrystal silicon layer, the second silicide layer is positioned over the second silicon-containing layer, the sidewall dielectric layer is located between the first silicon-containing layer and the second silicon-containing layer, and a top portion of the sidewall dielectric layer is pointed.

The semiconductor device having the structure in accordance with the above paragraph may achieve the same effects as those of the semiconductor devices described earlier.

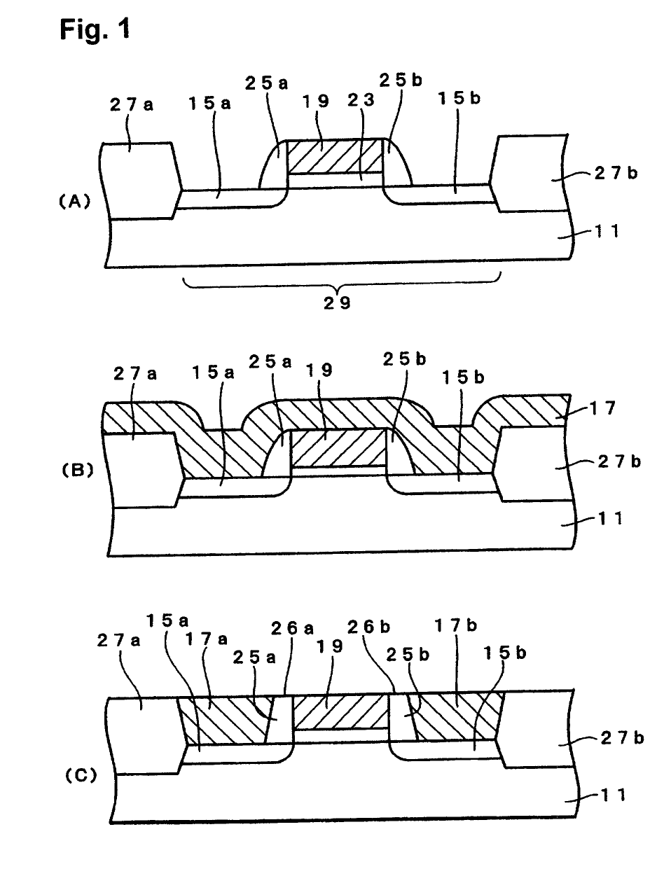

Certain preferred embodiments are discussed below with reference to FIGS. 1-4.

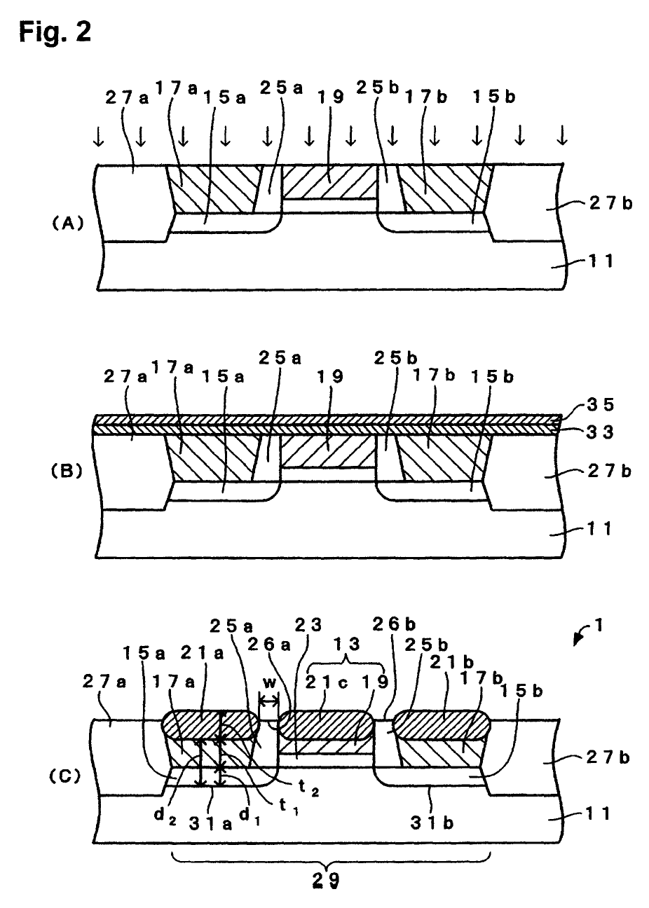

FIG. 2(C) shows a cross-sectional view of a MOS field effect transistor 1 in accordance with a first embodiment of the present invention. The MOS field effect transistor 1 is an example of a semiconductor device. The MOS field effect transistor 1 is equipped with a p type silicon substrate 11, a gate electrode 13, an n⁺ type source region 15a and an n⁺ type drain region 15b.

Field oxide layers 27a and 27b are located over the surface of the p type silicon substrate 11. The MOS field effect transistor 1 is formed in an element forming region 29 that is defined by the field oxide layers 27a and 27b.

A gate electrode 13 is located over the element forming region 29 through a gate dielectric layer 23. The gate electrode 13 preferably includes a polycrystal silicon layer 19 and a silicide layer 21c that is located over the polycrystal silicon layer 19. The polycrystal silicon layer 19 is one example of a conduction layer as well as one example of a first silicon-containing layer. The gate dielectric layer 23 is formed from a silicon oxide layer. Instead of the silicon oxide layer, another dielectric layer, such as, for example, a silicon nitride layer can be used.

The n⁺ type source region 15a is located between the field oxide layer 27a and the gate electrode 13, and in the p type silicon substrate 11. The n⁺ type source region 15a is one example of a source/drain region. The n⁺ type source region 15a has a preferred depth d₁ that is 500˜1000 Angstrom. The n⁺ type source region 15a and the p type silicon substrate 11 form a pn junction 31a.

A polycrystal silicon layer 17a is located over the n⁺ type source region 15a. The polycrystal silicon layer 17a is one example of a silicon-containing layer, as well as one example of a second silicon-containing layer. The polycrystal silicon layer 17a has a preferred thickness t₁ that is 500 Angstrom or less.

A silicide layer 21a is located over the polycrystal silicon layer 17a. The silicide layer 21a is one example of a second silicide layer. The silicide layer 21a has a preferred thickness t₂ of 300˜500 Angstrom. A distance d₂ between a bottom of the source region 15a and a bottom of the silicide layer 21a is preferably 1000˜1500 Angstrom. The distance d₂ is a distance with which leak current at the pn junction 31a does not increase. The n⁺ type drain region 15b is located between the field oxide layer 27b and the gate electrode 13, and in the p type silicon substrate 11. The n⁺ type drain region 15b is one example of a source/drain region. The n⁺ type drain region 15b has a depth that is the same as the depth d₁ of the n⁺ type source region 15a. The n⁺ type drain region 15b and the p type silicon substrate 11 form a pn junction 31b.

A polycrystal silicon layer 17b is located over the n⁺ type drain region 15b. The polycrystal silicon layer 17b is one example of a silicon-containing layer, as well as one example of a second silicon-containing layer. The polycrystal silicon layer 17b has a thickness that is the same as the thickness t₁ of the polycrystal silicon layer 17a.

A silicide layer 21b is located over the polycrystal silicon layer 17b. The silicide layer 21b is one example of a second silicide layer. The silicide layer 21b has a thickness that is the same as the thickness t₂ of the silicide layer 21a. A distance between a bottom of the n⁺ type drain region 15b and a bottom of the silicide layer 21b is the same as the distance d₂.

A sidewall dielectric layer 25a is located on one side surface of the gate electrode 13. The sidewall dielectric layer 25a is formed from, for example, a silicon nitride layer or a silicon oxide layer. The sidewall dielectric layer 25a has a top portion 26a having a width W that can avoid contact between the silicide layer 21a and the silicide layer 21c. The width W of the top portion 26a is, for example, 500˜1000 Angstrom.

A sidewall dielectric layer 25b is located on the other side surface of the gate electrode 13. The sidewall dielectric layer 25b is formed from, for example, a silicon nitride layer or a silicon oxide layer. The sidewall dielectric layer 25b has a top portion 26b having a width W that is the same as the width W of the top portion 26a, and that can avoid contact between the silicide layer 21b and the silicide layer 21c.

A method for manufacturing the MOS field effect transistor 1 shown in FIG. 2(C) is described with reference to FIG. 1 and FIG. 2. FIG. 1 and FIG. 2 are process illustrations that are used to describe the method for manufacturing the MOS field effect transistor 1.

As shown in FIG. 1(A), field oxide layers 27a and 27b are formed in a p type silicon substrate 11, using a LOCOS (local oxidation of silicon) method, for example. The field oxide layers 27a and 27b define an element forming region 29.

A silicon oxide layer that becomes a gate dielectric layer 23 is formed over the p type silicon substrate 11 in the element forming region 29 by, for example, thermal oxidation. A polycrystal silicon layer 19 having a preferred thickness of 2000˜3000 Angstrom is formed over the silicon oxide layer by, for example, a CVD method.

The polycrystal silicon layer 19 is patterned by, for example, photolithography and etching. The patterned polycrystal silicon layer 19 forms a part of the gate electrode.

An n type impurity (for example, As, P) is ion-implanted in the p type silicon substrate 11 using the polycrystal silicon layer 19 and the field oxide layers 27a and 27b as masks to form an n⁺ type source region 15a and an n⁺ type drain region 15b.

A silicon nitride layer is formed over the entire surface of the p type silicon substrate 11 by, for example, a CVD method. The entire surface of the silicon nitride layer is etched to form sidewall dielectric layers 25a and 25b on sides of the polycrystal silicon layer 19.

As shown in FIG. 1(B), an amorphous silicon layer 17 having a preferred thickness of 2000˜3000 Angstrom is formed over the surface of the p type silicon substrate 11 by, for example, a CVD method. A polycrystal silicon layer can be formed instead of the amorphous silicon layer 17. It is noted that the amorphous silicon layer 17 changes to a polycrystal silicon layer by a heat treatment to be conducted in a later stage. The amorphous silicon layer 17 is herebelow referred to as a polycrystal silicon layer (amorphous silicon layer) 17.

As shown in FIG. 1(C), the polycrystal silicon layer (amorphous silicon layer) 17, the polycrystal silicon layer 19, the sidewall dielectric layers 25a and 25b, and the field oxide layers 27a and 27b are polished by a CMP method. As a result, the polycrystal silicon layer (amorphous silicon layer) 17 becomes a polycrystal silicon layer (amorphous silicon layer) 17a over the n⁺ type source region 15a and a polycrystal silicon layer (amorphous silicon layer) 17b over the n⁺ type drain region 15b. The polycrystal silicon layer (amorphous silicon layer) 17a is isolated from the polycrystal silicon layer 19 by the sidewall dielectric layer 25a. Also, the polycrystal silicon layer (amorphous silicon layer) 17b is isolated from the polycrystal silicon layer 19 by the sidewall dielectric layer 25b.

The polishing amount is determined in such a manner to provide the width W shown in FIG. 2(C) and the distance d₂ shown in FIG. 2(C). In other words, if the polishing amount is too little, the width of the top portion 26a of the sidewall dielectric layer 25a does not reach a value that can avoid contact between the silicide layer 21a and the silicide layer 21c. Also, the width of the top portion 26b of the sidewall dielectric layer 25b does not reach a value that can avoid contact between the silicide layer 21b and the silicide layer 21c.

On the other hand, if the polishing amount is excessive, the thickness of the polycrystal silicon layer (amorphous silicon layer) 17a, 17b becomes small. If the silicide layers 21a and 21b are made thicker under this condition, the distance between the bottom of the silicide layer 21a (21b) and the bottom of the n⁺ type source region 15a (the n⁺ type drain region 15b) becomes short, and therefore leak current at the pn junctions 31a and 31b increases.

After the polishing step by a CMP method, the polishing agent and the like that are used in the CMP method may be removed by a sacrificial oxidation.

Then, as shown in FIG. 2(A), a p type impurity (for example, B) or an n type impurity (for example, As, P) is ion-implanted in the surface of the p type silicon substrate 11. As a result, the resistance of the polycrystal silicon layer (amorphous silicon layer) 17a, 17b and the polycrystal silicon layer 19 is lowered. It is noted that the ion-implantation is preferably conducted under conditions in which the impurity diffuses to the bottom of the polycrystal silicon layer 19. This prevents the gate electrode 13 from becoming depleted.

As shown in FIG. 2(B), a Ti layer 33 having a preferred thickness of 200˜400 Angstrom is formed over the surface of the p type silicon substrate 11 by, for example, a sputtering method. Instead of the Ti layer 33, a Co layer having a preferred thickness of 100˜200 Angstrom may be formed. Alternatively, another high melting point metal that can form a silicide layer may be formed.

Then, a TiN layer 35 having a preferred thickness of 100˜500 Angstrom is formed over the Ti layer 33 by, for example, a sputtering method. The TiN layer 35 is formed for the following reasons. If oxygen is present during the silicide reaction, problems occur. For example, the reaction starting temperature rises; the silicide coheres at a lower temperature and thus the wiring resistance increases; and so forth. To prevent the occurrence of the problems, the Ti layer 33 is capped by the TiN layer 35.

As shown in FIG. 2(C), the Ti layer 33 is heat-treated by, for example, a lamp anneal. As a result, silicide layers 21a, 21b and 21c, which are titanium silicide layers, are formed. Then, non-reacted portions of the Ti layer 33 are removed by, for example, a wet etching method. Since the top portion 26a (top portion 26b) has the width W, the silicide layer 21a is isolated from the silicide layer 21c, and also the silicide layer 21b is isolated from the silicide layer 21c.

By the steps described above, the MOS field effect transistor 1 is completed. In accordance with the manufacturing method embodiment described above, the amorphous silicon layer 17 is formed by a CVD method, as shown in FIG. 1(B). Therefore, the silicon-containing layer can be more readily formed over the n⁺ type source region 15a (n⁺ type drain region 15b) compared to the case in which a monocrystal silicon layer is formed by an epitaxial growth method. A second embodiment of the present invention to be described next may provide the same effects.

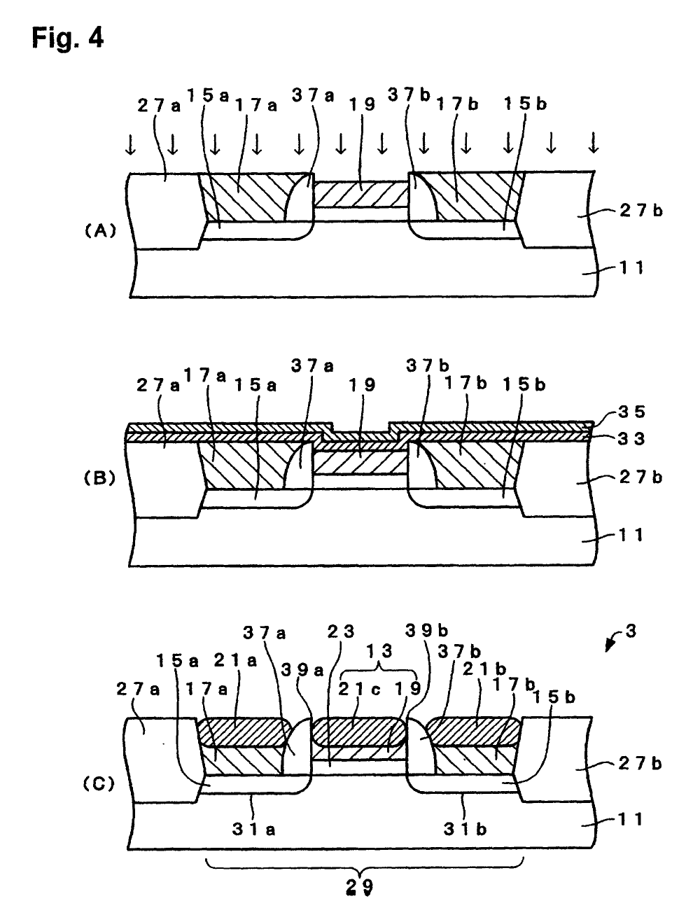

FIG. 4(C) shows a cross-sectional view of a MOS field effect transistor 3 in accordance with a second embodiment of the present invention. The MOS field effect transistor 3 is an example of a semiconductor device. In the MOS field effect transistor 3 of the second embodiment, elements having the same functions as those of the MOS field effect transistor 1 of the first embodiment shown in FIG. 2(C) are indicated by the same reference numbers. Portions of the MOS field effect transistor 3 that are different from those of the MOS field effect transistor 1 are described, and the description of the same portions is omitted.

The MOS field effect transistor 3 has sidewall dielectric layers in a similar manner as the MOS field effect transistor 1. Top portions 39a and 39b of the respective sidewall dielectric layers 37a and 37b of the MOS field effect transistor 3 are pointed. This is because the sidewall dielectric layers 37a and 37b are not polished by a CMP method. A detailed description thereof is provided in the next section relating to a method for manufacturing a device.

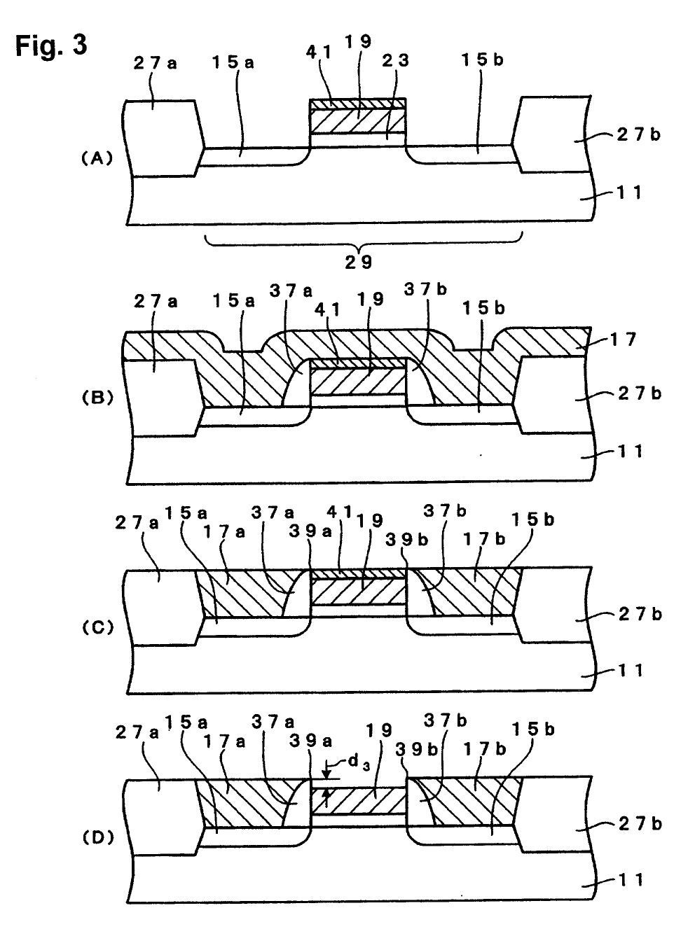

A method for manufacturing the MOS field effect transistor 3 shown in FIG. 4(C) is described with reference to FIG. 3 and FIG. 4. FIG. 3 and FIG. 4 are process illustrations that are used to describe the method for manufacturing the MOS field effect transistor 3.

As shown in FIG. 3(A), field oxide layers 27a and 27b are formed in a p type silicon substrate 11. The same forming method used in the first embodiment can be used. The field oxide layers 27a and 27b define an element forming region 29.

For example, a silicon oxide layer that becomes a gate dielectric layer 23 is formed over the p type silicon substrate 11 in the element forming region 29. A polycrystal silicon layer 19 is formed over the silicon oxide layer. The same forming methods used in the first embodiment can be used.

A TiN layer 41 is formed over the polycrystal silicon layer 19 by, for example, a reactive sputtering method. The TiN layer 41 is one example of an upper layer. The thickness of the TiN layer 41 is, for example, 300˜1000 Angstrom.

The TiN layer 41 and the polycrystal silicon layer 19 are patterned by, for example, photolithography and etching. The patterned polycrystal silicon layer 19 forms a part of the gate electrode.

An n type impurity (for example, As, P) is ion-implanted in the p type silicon substrate 11 using the TiN layer 41 and the field oxide layers 27a and 27b as masks to form an n⁺ type source region 15a and an n⁺ type drain region 15b.

A silicon nitride layer is formed over the entire surface of the p type silicon substrate 11 by, for example, a CVD method, as shown in FIG. 3(B). The entire surface of the silicon nitride layer is etched to form sidewall dielectric layers 37a and 37b on sides of the polycrystal silicon layer 19 and the TiN layer 41.

Next, an amorphous silicon layer 17 having a preferred thickness of 2000˜3000 Angstrom is formed over the surface of the p type silicon substrate 11 by, for example, a CVD method. A polycrystal silicon layer can be formed instead of the amorphous silicon layer 17. It is noted that the amorphous silicon layer 17 changes to a polycrystal silicon layer by a heat treatment to be conducted in a later stage. The amorphous silicon layer 17 is hereunder referred to as a polycrystal silicon layer (amorphous silicon layer) 17.

As shown in FIG. 3(C), the polycrystal silicon layer (amorphous silicon layer) 17 and the field oxide layers 27a and 27b are polished by a CMP method. As a result, the polycrystal silicon layer (amorphous silicon layer) 17 becomes a polycrystal silicon layer (amorphous silicon layer) 17a over the n⁺ type source region 15a and a polycrystal silicon layer (amorphous silicon layer) 17b over the n⁺ type drain region 15b. Since the sidewall dielectric layers 37a and 37b are not polished by a CMP method, their top portions 39a and 39b are pointed.

As shown in FIG. 3(D), the TiN layer 41 is removed by, for example, a mixed solution of ammonia water and hydrogen peroxide water, to thereby expose the polycrystal silicon layer 19. As a result, the polycrystal silicon layers (amorphous silicon layers) 17a and 17b are separated from the polycrystal silicon layer 19 by a distance d₃ (preferably 300˜1000 Angstrom) that is the thickness of the TiN layer 41. As a result, the polycrystal silicon layer 19 and the polycrystal silicon layer (amorphous silicon layer) 17a can be placed in a positional relation in which the silicide layer 21c and the silicide layer 21a do not contact each other, and the polycrystal silicon layer 19 and the polycrystal silicon layer (amorphous silicon layer) 17b can be placed in a positional relation in which the silicide layer 21c and the silicide layer 21b do not contact each other.

Then, as shown in FIG. 4(A), a p type impurity or an n type impurity is ion-implanted in the surface of the p type silicon substrate 11. This step is the same as the step shown in FIG. 2(A) of the first embodiment, and therefore its detailed description is omitted.

As shown in FIG. 4(B), a Ti layer 33 is formed over the entire surface of the p type silicon substrate 11 by, for example, a sputtering method. Then, a TiN layer 35 is formed over the Ti layer 33. The step shown in FIG. 4(B) is the same as the step shown in FIG. 2(B) of the first embodiment, and therefore its detailed description is omitted.

As shown in FIG. 4(C), the Ti layer 33 is heat treated. As a result, silicide layers 21a, 21b and 21c, which are titanium silicide layers, are formed. Then, non-reacted portions of the Ti layer 33 are removed. Since the polycrystal silicon layers (amorphous silicon layers) 17a and 17b are separated from the polycrystal silicon layer 19 by the distance d₃, the silicide layer 21a can be isolated from the silicide layer 21c, and the silicide layer 21b can be isolated from the silicide layer 21c. The step shown in FIG. 4(C) is the same as the step shown in FIG. 2(C) of the first embodiment, and therefore its detailed description is omitted.

By the steps described above, the MOS field effect transistor 3 is completed. In accordance with the manufacturing method described above, the polishing conditions in the CMP method may be set such that the silicon is polished but the TiN is not polished. As a result, the TiN layer 41 can function as a polishing stopper. As a result, the polycrystal silicon layer (amorphous silicon layer) 17 formed over the n⁺ type source region 15a and the n⁺ type drain region 15b shown in FIG. 3(B) can be prevented from being excessively polished.

It is noted that, although the MOS field effect transistor 1 or 3 is an n type, the present invention is also applicable to a p type MOS field effect transistor.

The present invention is not limited to the embodiments described above, and many modifications can be made within the scope of the subject matter of the present invention.

What is claimed:

1. A method for manufacturing a semiconductor device, the method comprising:
forming a conduction layer that becomes a component of a gate electrode;
forming a source/drain region;
forming a silicon-containing layer including at least one of an amorphous silicon layer and a polycrystal silicon layer in a manner to cover the source/drain region and the conduction layer;
partially removing the silicon-containing layer to leave the silicon-containing layer over the source/drain region; and
forming a silicide layer over the silicon-containing layer over the source/drain region.

2. A method for manufacturing a semiconductor device according to claim 1, wherein partially removing the silicon-containing layer to leave the silicon-containing layer over the source/drain region includes the step of polishing the silicon-containing layer by a CMP (Chemical Mechanical Polishing) method.

3. A method for manufacturing a semiconductor device according to claim 2, further comprising forming a CMP stop layer over the polycrystal silicon layer.

4. A method for manufacturing a semiconductor device according to claim 3, wherein the CMP stop layer comprises a nitride layer.

5. A method for manufacturing a semiconductor device according to claim 4, wherein the nitride layer comprises titanium nitride.

6. A method for manufacturing a semiconductor device according to claim 3, further comprising removing the CMP stop layer prior to forming the silicide layer.

7. A method for manufacturing a semiconductor device, the method comprising:
forming a first silicon-containing layer that becomes a component of a gate electrode;
forming a source/drain region;
forming a sidewall dielectric layer on a side surface of the first silicon-containing layer;
forming a second silicon-containing layer including at least one of an amorphous silicon layer and a polycrystal silicon layer in a manner to cover the source/drain region and the first silicon-containing layer;
partially removing the second silicon-containing layer to leave the second silicon-containing layer over the source/drain region; and
forming a first silicide layer over the first silicon-containing layer and a second silicide layer over the second silicon-containing layer on the source/drain region.

8. A method for manufacturing a semiconductor device according to claim 7, wherein partially removing the second silicon-containing layer to leave the second silicon-containing layer over the source/drain region includes the step of polishing the first silicon-containing layer, the second silicon-containing layer and the sidewall dielectric layer by a CMP (Chemical Mechanical Polishing) method.

9. A method for manufacturing a semiconductor device, the method comprising:
forming a first silicon-containing layer that becomes a component of a gate electrode;
forming an upper layer over the first silicon-containing layer;
forming a source/drain region;
forming a sidewall dielectric layer on a side surface of a structure including the first silicon-containing layer and the upper layer;
forming a second silicon-containing layer including at least one of an amorphous silicon layer and a polycrystal silicon layer in a manner to cover the source/drain region and the upper layer;
partially removing the second silicon-containing layer to leave the second silicon-containing layer over the source/drain region and to expose the upper layer;
removing the upper layer; and
forming a first silicide layer over the first silicon-containing layer and a second silicide layer over the second silicon-containing layer on the source/drain region.

10. A method for manufacturing a semiconductor device according to claim 9, wherein the partially removing the second silicon-containing layer to leave the second silicon-containing layer over the source/drain region and to expose the upper layer includes the step of polishing the second silicon-containing layer by a CMP (Chemical Mechanical Polishing) method.

11. A semiconductor device having a silicide layer, comprising:
a silicon-containing layer and a source/drain region, wherein
the silicon-containing layer is positioned over the source/drain region,
the silicon-containing layer includes at least one of an amorphous silicon layer and a polycrystal silicon layer, and
the silicide layer is positioned over the silicon-containing layer.

12. A semiconductor device comprising;
a source/drain region, a first silicon-containing layer, a second silicon-containing layer, a first silicide layer, a second silicide layer and a sidewall dielectric layer, wherein
the first silicon-containing layer and the first silicide layer form a gate electrode,
the second silicon-containing layer is positioned over the source/drain region,
the second silicon-containing layer includes at least one of an amorphous silicon layer and a polycrystal silicon layer,
the second silicide layer is positioned over the second silicon-containing layer,
the sidewall dielectric layer is located between the first silicon-containing layer and the second silicon-containing layer, and
a top portion of the sidewall dielectric layer includes a polished surface.

13. A semiconductor device according to claim 12, wherein the polished surface is flat.

14. A semiconductor device comprising;
a source/drain region, a first silicon-containing layer, a second silicon-containing layer, a first silicide layer, a second silicide layer and a sidewall dielectric layer, wherein
the first silicon-containing layer and the first silicide layer form a gate electrode,
the second silicon-containing layer is positioned over the source/drain region,
the second silicon-containing layer includes at least one of an amorphous silicon layer and a polycrystal silicon layer,
the second silicide layer is positioned over the second silicon-containing layer,
the sidewall dielectric layer is located between the first silicon-containing layer and the second silicon-containing layer, and
a top portion of the sidewall dielectric layer is pointed.
